(19) United States
(12) Patent Application Publication
(10) Pub. No.: US 2012/0160316 A1
(43) Pub. Date: Jun. 28, 2012

(54) REFLECTION BLOCKING FILM AND METHOD OF MANUFACTURING THE SAME

(75) Inventors: Tae Young KIM, Seoul (KR); Seung Yun Oh, Gyeonggi-do (KR); In Taek Song, Gyeonggi-do (KR); Jin Mun Ryu, Gyeonggi-do (KR)

(73) Assignee: SAMSUNG ELECTRO-MECHANICS CO., LTD.

(21) Appl. No.: 13/305,314

(22) Filed: Nov. 28, 2011

(30) Foreign Application Priority Data
Dec. 22, 2010 (KR) 10-2010-0132166

(51) Int. Cl. H01L 31/0216; H01L 31/18

(52) U.S. Cl. 136/256; 438/72; 257/E31.119

(57) ABSTRACT

A reflection blocking film provided on a solar cell includes a transparent substrate with a plurality of patterns having incident light collected on the top surface thereof, and a reflector on the bottom surface of the transparent substrate and with holes through which the collected incident light is transmitted. A method of manufacturing a reflection blocking film includes: forming a plurality of patterns on the top surface of a transparent substrate; coating a photo resin on a bottom surface of the transparent substrate; exposing to irradiate light to the top surface of the transparent substrate to react the light collected by the pattern with the photo resin; developing to lift off a portion, which does not receive light, by using a developer during the exposing; coating a reflector on the bottom surface of the transparent substrate; and forming holes by lifting off the photo resin interposed in the reflector.

### CROSS REFERENCE(S) TO RELATED APPLICATIONS

This application claims the benefit under 35 U.S.C. Section 119 of Korean Patent Application Serial No. 10-2010-0132166, entitled “Reflection Blocking Film And Method Of Manufacturing The Same” filed on Dec. 22, 2010, which is hereby incorporated by reference in its entirety into this application.

### BACKGROUND OF THE INVENTION

1. Technical Field

The present invention relates to a reflection blocking film capable of reducing loss of light due to the reflection of light incident to a solar cell and trapping light reflected from the surface of the solar cell, and a method of manufacturing the same.

2. Description of the Related Art

In the related art, as a structure to prevent the reflection of light incident to a solar cell, there is a structure to prevent loss of light due to the reflection of incident light by making a pyramid-shaped structure or forming pores or ruggedness using a technology of etching the surface of the solar cell, etc. However, only the simple surface treatment cannot prevent all the loss of light. Therefore, a cover glass or a cover sheet is provided and the surface of the sheet is formed with the above-mentioned pyramid structure, a porous structure, a rugged structure, etc., thereby maximally trapping light reflected from the surface of the solar cell. However, in the case of the scheme, it is difficult to trap reflection light and scattering light within a threshold angle at each boundary surface, such that there is a limitation in improving a current value of a solar cell.

### SUMMARY OF THE INVENTION

An object of the present invention is to provide a reflection blocking film capable of maximally trapping light reflected from a surface of a solar cell.

Another object of the present invention is to provide a method of manufacturing a reflection blocking film capable of forming a reflector and holes provided on the reflector by directly using patterns formed on a transparent substrate in order to acquire the maximum efficiency of the reflection blocking film.

Another object of the present invention is to provide a reflection blocking film restricting numerical apertures of patterns to a predetermined number or more in order to increase the efficiency of the patterns (light collecting unit).

According to an exemplary embodiment of the present invention, there is provided a reflection blocking film provided on a solar cell, including: a transparent substrate formed with a plurality of patterns having incident light collected on the top surface thereof; and a reflector provided on the bottom surface of the transparent substrate and formed with holes through which the collected incident light is transmitted.

The hole may be provided as the number corresponding to the plurality of patterns.

The holes may be each provided in the central portion of the pattern.

The pattern may be a hemispherical shape.

The pattern may be formed so that the contact surface with the transparent substrate is a polygonal shape.

The numerical aperture of the pattern may be set to be 0.2 or more.

According to an exemplary embodiment of the present invention, there is provided a method of manufacturing a reflection blocking film provided on a solar cell, including: forming a plurality of patterns on the top surface of a transparent substrate; coating a photo resin on a bottom surface of the transparent substrate; exposing to irradiate light to the top surface of the transparent substrate to react the light collected by the pattern with the photo resin; developing to lift off a portion, which does not receive light, by using a developer during the exposing; coating a reflector on the bottom surface of the transparent substrate; and forming holes by lifting off the photo resin interposed in the reflector.

### BRIEF DESCRIPTION OF THE DRAWINGS

FIG. 1 is a cross-sectional view of a reflection blocking film according to the exemplary embodiment of the present invention;

FIG. 2 is a plan view of the reflection blocking film according to the exemplary embodiment of the present invention;

FIG. 3 is a bottom view of the reflection blocking film according to the exemplary embodiment of the present invention;

FIG. 4 is a cross-sectional view of the reflection blocking film according to the exemplary embodiment of the present invention; and

FIGS. 5A to 5F are flow charts showing a process of manufacturing the reflection blocking film according to the exemplary embodiment of the present invention.

### DESCRIPTION OF THE PREFERRED EMBODIMENTS

Hereinafter, exemplary embodiments will be described in detail with reference to the accompanying drawings. Prior to the detailed description of the present invention, terms or words used in the specification and the appended claims should not be construed as having normal or lexical meanings, and should be construed as having meanings and concepts which conform with the spirit of the present invention according to a principle that the inventor can properly define the concepts of the terms in order to describe his/her own invention in the best way.

Accordingly, embodiments disclosed in the specification and configurations shown in the accompanying drawings are just the most preferred embodiments, but are not limited to the spirit and scope of the present invention. Therefore, at the time of this application, it will be appreciated that various equivalents and modifications may be included within the spirit and scope of the present invention.

Hereinafter, a structure of a reflection blocking film and a method of manufacturing the same according to an exemplary embodiment of the present invention will be described.

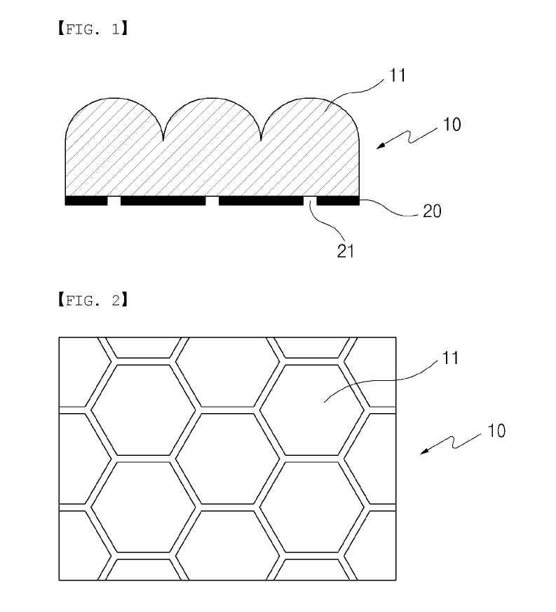

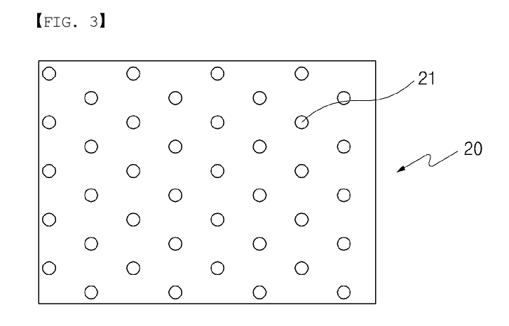

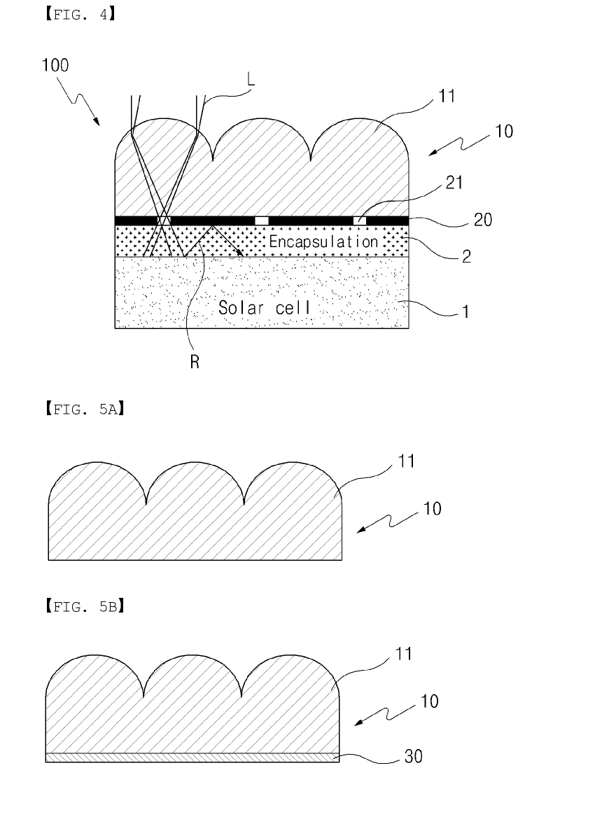

FIG. 1 is a cross-sectional view of a reflection blocking film according to the exemplary embodiment of the present invention, FIG. 2 is a plan view of the reflection blocking film according to the exemplary embodiment of the present invention, and FIG. 3 is a bottom view of the reflection blocking film according to the exemplary embodiment of the present invention.

As can be appreciated from FIGS. 1 to 3, the present invention relates to a reflection blocking film 100 provided on a solar cell, which may be configured to include a transparent substrate 10 and a reflector 20.

The transparent substrate 10 is provided on a top portion of a solar cell, that is, an incident portion of sunlight. The top surface of the transparent substrate 10 are provided with a plurality of patterns 11 light collecting incident light L. Light incident to the transparent substrate 10 penetrates through the transparent substrate 10 and is transferred to the solar cell on the bottom portion thereof. The pattern 11 is provided in a hemispherical shape, which serves to collect incident light to substantially focus the collected sunlight to a single point.

In the pattern 11, a contact surface with the transparent substrate 10 may be provided in a polygonal shape in terms of the efficiency of space use. That is, FIG. 2 shows an example where the contact surface of the pattern 11 and the transparent substrate 10 is a hexagonal shape in the reflection blocking film. The present invention is not limited thereto and can use various polygonal shapes such as a triangle, a quadrangle, a pentagon, a heptagon, an octagon, or the like.

In addition, a numerical aperture of the pattern 11 may be set to be 0.2 or more. The numerical aperture (NA) is an important value of determining performance of a light collector such as resolution, depth of focus, brightness, or the like, and is a value defined by NA=1/(2*f*d) (f: focal distance of lens, d: diameter of lens). The larger the NA, the better the performance of light collection becomes and the shorter the focal distance becomes. Generally, the high-efficiency light collector has a large numerical aperture. The exemplary embodiment of the present invention uses the numerical aperture of 0.2 or more in consideration of the numerical aperture. When the numerical aperture is set to be 0.2 or less, the large diffraction effect is generated such that the light collection is not efficiently made.

The reflector 20 is provided on the bottom surface of the transparent substrate 10 and is provided holes 21 through which the collected incident light is transmitted. The reflector 20 serves to trap light formed from the reflection of the incident light through the holes 21. In the present exemplary embodiment of the present invention, the pattern 11 collects the incident light to substantially focus the collected incident sunlight to the single point. The point corresponds to the holes 21. In the exemplary embodiment of the present invention, the holes 21 are provided as the number corresponding to the plurality of patterns 11 and the holes 21 is provided to be disposed at the central portion of the pattern 11 in order to increase the efficiency of light collection.

The exemplary embodiment of the present invention uses light without wasting light due to the leakage of reflection of incident sunlight in order to increase the utilization efficiency of sunlight. To this end, the incident light may be reflected from the reflector 20 and may be again used for the solar cell.

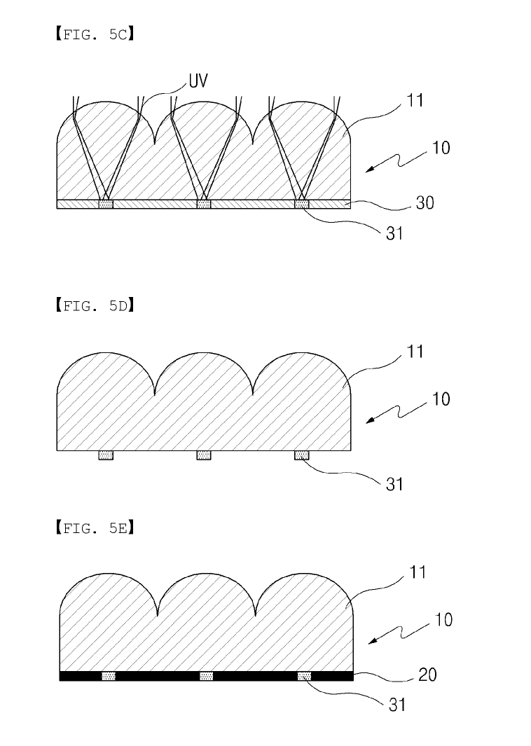

To this end, in the exemplary embodiment of the present invention, the sunlight is input and collected by the pattern 11 of the transparent substrate 10 provided on the top portion of the solar cell and the collected light is transferred to the solar cell transmitted to the hole 21. However, the reflector 20 does not use the transferred sunlight 100% in the solar cell, reflects some thereof, and again reflects the reflected light to the solar cell. A mechanism of trapping the reflection light of sunlight will be described with reference to FIG. 4.

FIG. 4 is a cross-sectional view for explaining an operation of the reflection blocking film according to the exemplary embodiment of the present invention. As shown in FIG. 4, the reflection blocking film 100 is provided on the top portion of the solar cell 1, having an encapsulating layer 2 provided therebetween.

When the sunlight is incident to the pattern 11 provided on the transparent substrate 10, the incident light is focused to a single point by each pattern 11. In the exemplary embodiment of the present invention, the holes 21 are provided in the point to which the incident light is focused, such that the focused incident light penetrates through the reflector 20 and is transmitted to the encapsulating layer 2 and reaches the solar cell 1. However, the transmitted incident light does not use 100% in the solar cell 1 and some thereof is reflected (see the reflection light (R) of FIG. 4). The reflection light is again reflected to the solar cell 1 by the reflector 20 so that the solar cell 1 can use the reflection light.

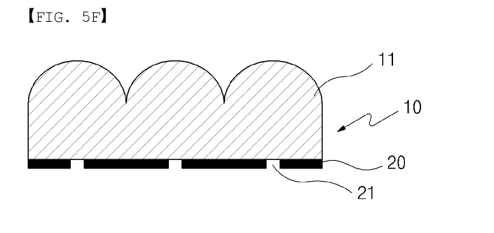

FIGS. 5A to 5F are flow charts showing a process of manufacturing the reflection blocking film according to the exemplary embodiment of the present invention. As shown in FIGS. 5A to 5F, the reflection blocking film 100 according to the exemplary embodiment of the present invention is configured to include a pattern forming step (S10), a coating step (S20), an exposing step (S30), a developing step (S40), a coating step (S50), and a hole forming step (S60). The exemplary embodiment of the present invention directly forms the reflector and the holes provided thereon by using the patterns formed on the transparent substrate in order to acquire the maximum efficiency of the reflection blocking film. This will be described below.

As shown in FIG. 5A, the pattern forming step (S10) is a step of forming the plurality of patterns 11 on the top surface of the transparent substrate 10. Generally, the plurality of patterns 11 are formed on the top surface of the transparent substrate 10 made of a glass material by various machining methods. The pattern 11 is based on the hemispherical shape and the contact portion of the pattern 11 and the transparent substrate 10 may be formed in a polygonal shape (triangle, quadrangle, pentagon, hexagon, heptagon, etc.) in terms of the efficiency of the space utilization.

As shown in FIG. 5B, the coating step (S20) is a step of coating a photo resin 30 on the bottom surface of the transparent substrate 10, which corresponds to a work providing the reflector 20 on the bottom portion of the transparent substrate 10. The photo resin 30 does not correspond to components of the exemplary embodiment of the present invention but corresponds to the intermediate unit for forming holes 21 on the reflector 20 during the manufacturing process thereof. That is, after the reflector 20 is coated with the photo resin 30 while remaining in a portion where the holes 21 are formed, the holes 21 are formed by lifting off the photo resin 30. Further, the photo resin 30 may use the negative photo resin, which has characteristics changing the nature of a portion receiving light.

As shown in FIG. 5C, the exposing step (S30) is a step of irradiating light to the top surface of the transparent substrate 10 to react the light collected by the pattern 11 with the photo resin. The light may use ultraviolet rays (UV). That is, the incident light is collected by the pattern 11 and is focused to a single point. The photo resin is cured by the focused light (reference numeral 31).

As shown in FIG. 5D, the developing step S40 is a step of lifting off a portion, which does not receive light, by a developer during the exposing step (S30) and the remaining photo resin 30 other than the exposing part 31 cured by receiving light is lifted off by the developer.

As shown in FIG. 5E, the coating step (S50) is a step of coating the reflector 20 on the bottom surface of the transparent substrate 10 and the exposing part 31 remains as it is during the developing step (S40) and the portion of lifting off the photo resin 30 by the developer is filled in the reflector 20. In this case, the reflector 20 is made of chromium (Cr), aluminum (Al), or the like.

As shown in FIG. 5F, the hole forming step (S60) is a step of lifting off the photo resin (that is, the exposing part 31) interposed in the reflector 20 to form the holes 21 and lifting off the exposing part 31 interposed between the reflectors 20 using a stripping liquid during the coating step S50.

When the reflection blocking film according to the exemplary embodiment of the present invention is manufactured by the above-mentioned method, the reflector 20 including the holes 21 attached on the transparent substrate 10 is formed by the pattern 11 to be directly used, such that the pattern 11 and the holes 21 provided up and down can be precisely aligned, thereby making it possible to maximize the utilization efficiency of sunlight.

As set forth above, the exemplary embodiment of the present invention can provide the reflection blocking film capable of maximally trapping the light reflected from the surface of the solar cell.

In addition, the exemplary embodiment of the present invention can provide the method of manufacturing a reflection blocking film forming the reflector and the holes provided on the reflector by directly using the patterns formed on the transparent substrate, thereby making it possible to acquire the maximum efficiency of the reflector blocking film.

Further, the exemplary embodiment of the present invention can maximize the efficiency of the reflection blocking film by restricting the numerical apertures of the patterns to the predetermined number or more in order to increase the efficiency of the patterns (light collecting unit).

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A reflection blocking film provided on a solar cell, comprising:
a transparent substrate formed with a plurality of patterns having incident light collected on the top surface thereof; and
a reflector provided on the bottom surface of the transparent substrate and formed with holes through which the collected incident light is transmitted.

2. The reflection blocking film according to claim 1, wherein the hole is provided as the number corresponding to the plurality of patterns.

3. The reflection blocking film according to claim 2, wherein the holes are each provided in the central portion of the pattern.

4. The reflection blocking film according to claim 1, wherein the pattern is a hemispherical shape.

5. The reflection blocking film according to claim 4, wherein the pattern is formed so that the contact surface with the transparent substrate is a polygonal shape.

6. The reflection blocking film according to claim 1, wherein the numerical aperture of the pattern is set to be 0.2 or more.

7. A method of manufacturing a reflection blocking film provided on a solar cell, comprising:
forming a plurality of patterns on the top surface of a transparent substrate;
coating a photo resin on a bottom surface of the transparent substrate;
exposing to irradiate light to the top surface of the transparent substrate to react the light collected by the pattern with the photo resin;
developing to lift off a portion, which does not receive light, by using a developer during the exposing;
coating a reflector on the bottom surface of the transparent substrate; and
forming holes by lifting off the photo resin interposed in the reflector.
